(19) United States
(12) Patent Application Publication
(10) Pub. No.: US 2025/0126722 A1
(43) Pub. Date: Apr. 17, 2025

(54) CIRCUIT COMPENSATION METHOD APPLIED TO PATTERN DISPLACEMENT AND CIRCUIT STRUCTURE

(71) Applicant: Industrial Technology Research Institute, Hsinchu (TW)

(72) Inventors: Chieh-Wei Feng, Taoyuan City (TW); Cheng-Yueh Chang, Hsinchu County (TW); Tai-Jui Wang, Kaohsiung City (TW)

(73) Assignee: Industrial Technology Research Institute, Hsinchu (TW)

(21) Appl. No.: 18/916,714

(22) Filed: Oct. 16, 2024

Related U.S. Application Data
(60) Provisional application No. 63/590,786, filed on Oct. 17, 2023.

(30) Foreign Application Priority Data
Sep. 3, 2024 (TW) 113133183

(51) Int. Cl. H05K 3/40; H05K 1/11; H05K 1/18

(52) U.S. Cl. CPC H05K 3/4007; H05K 1/11; H05K 1/181; H05K 2203/166

(57) ABSTRACT

A circuit compensation method applied to pattern displacement includes: disposing at least one chip on a carrier; measuring a shift of the chip, performing circuit position compensation on a predetermined pattern of a redistribution layer, and calculating a resistance difference of the pattern before and after the circuit position compensation; estimating a circuit proportion and a range of resistance variation in the pattern needed for resistance compensation after the circuit position compensation according to the resistance difference; determining a compensation position and a scheme of circuit proportion and adjusting a circuit width, area, length, pattern, or combination thereof of a circuit within the circuit proportion according to the resistance difference; outputting a picture file of the pattern after the circuit position and resistance compensation; and forming the redistribution layer according to the picture file and electrically connecting the redistribution layer to the chip. A circuit structure is also provided.

### CROSS-REFERENCE TO RELATED APPLICATION

This application claims the priority benefit of U.S. Provisional Application No. 63/590,786, filed on Oct. 17, 2023 and Taiwan Application No. 113133183, filed on Sep. 3, 2024. The entirety of each of the above-mentioned patent applications is hereby incorporated by reference herein and made a part of this specification.

### TECHNICAL FIELD

The disclosure relates to a circuit compensation method and a circuit structure and also relates to a circuit compensation method applied to pattern displacement and a circuit structure.

### BACKGROUND

In the chip first packaging process, chip displacement may lead to inaccurate connection of contact signals, but through the compensation design of conductive circuits corresponding to chip displacement, the chip and conductive circuits may be correctly connected. However, in the circuit after the compensation design, the circuit resistance value changes due to the change in circuit length, making the electrical quality of the chip package not meet expectations.

Further, in the redistribution layer first chip packaging process, due to the different thermal expansion coefficients of the dielectric materials and the metal materials, circuits on large-scale substrates may have different shift conditions, which may lead to shift in each circuit layer. When the chip is finally bonded to the redistribution layer, in order to avoid the chip not being properly connected to the pad, the circuit layer may be adjusted to compensate for the pad position. However, in the circuit after the compensation design, the circuit resistance value changes due to the change in wire length, making the electrical quality of the circuit structure not meet expectations.

### SUMMARY

An embodiment of the disclosure provides a circuit compensation method applied to pattern displacement, and the method includes the following steps. At least one chip is disposed on a carrier. A shift of the chip is measured, circuit position compensation is performed on a predetermined pattern of a redistribution layer, and a resistance difference of the pattern of the redistribution layer before and after the circuit position compensation is calculated. A circuit proportion and a range of resistance variation in the pattern of the redistribution layer needed for resistance compensation after the circuit position compensation are estimated according to the resistance difference. A compensation position and a scheme of circuit proportion are determined, and a circuit width, an area, a length, a pattern, or a combination thereof of a circuit within the circuit proportion are adjusted according to the resistance difference. A picture file of the pattern of the redistribution layer after the circuit position compensation and the resistance compensation is outputted. The redistribution layer is formed on the carrier according to the picture file, and the redistribution layer is electrically connected to the chip.

An embodiment of the disclosure further provides a circuit compensation method applied to pattern displacement, and the method includes the following steps. A plurality of layers of circuits are stacked on a carrier. Shifts of the layers of circuits are measured, and circuit position compensation is performed on a predetermined pattern of a top circuit to be formed on the layers of circuits so that a signal is connected normally. A resistance difference between a pattern of the top circuit after the circuit position compensation and the predetermined pattern is calculated. A circuit width, an area, a length, a pattern, or a combination thereof of a circuit within a circuit proportion of the pattern of the top circuit after the circuit position compensation are adjusted according to the resistance difference to achieve resistance compensation. The pattern of the top circuit after the circuit position compensation and the resistance compensation is outputted. The top circuit on the layers of circuits is formed according to the pattern of the top circuit after the circuit position compensation and the resistance compensation.

An embodiment of the disclosure further provides a circuit structure including a carrier, a redistribution layer, and at least one chip. The redistribution layer is disposed on the carrier and has a normal circuit located in a second region and a resistance compensation structure located in a first region. The resistance compensation structure has a circuit proportion and has a different circuit width, a different area, a different length, a different pattern, or a combination thereof compared to the normal circuit. The at least one chip is located on the carrier and is electrically connected to the redistribution layer. Resistance of the circuit structure does not change due to chip displacement.

Several exemplary embodiments accompanied with figures are described in detail below to further describe the disclosure in details.

### BRIEF DESCRIPTION OF THE DRAWINGS

The accompanying drawings are included to provide a further understanding, and are incorporated in and constitute a part of this specification. The drawings illustrate exemplary embodiments and, together with the description, serve to explain the principles of the disclosure.

FIG. 1 is a flow chart of a circuit compensation method applied to pattern displacement according to an embodiment of the disclosure.

FIG. 2A to FIG. 2E are schematic top views illustrating the process flow of the circuit compensation method applied to pattern displacement of FIG. 1.

FIG. 3 is a curve graph of variation of circuit resistance with circuit width compensation.

FIG. 4A to FIG. 4K are schematic top views illustrating a circuit before and after resistance compensation in the various embodiments of resistance compensation of FIG. 1.

FIG. 5A to FIG. 5E are schematic top views illustrating a circuit structure before and after resistance compensation according to the embodiments of the disclosure.

FIG. 5F is a schematic top view illustrating the circuit structure after resistance compensation according to an embodiment of the disclosure.

FIG. 6 is a flow chart of a circuit compensation method applied to pattern displacement according to another embodiment of the disclosure.

FIG. 7A to FIG. 7E are schematic top views illustrating the process flow of the circuit compensation method applied to pattern displacement of FIG. 6.

### DETAILED DESCRIPTION OF DISCLOSURED EMBODIMENTS

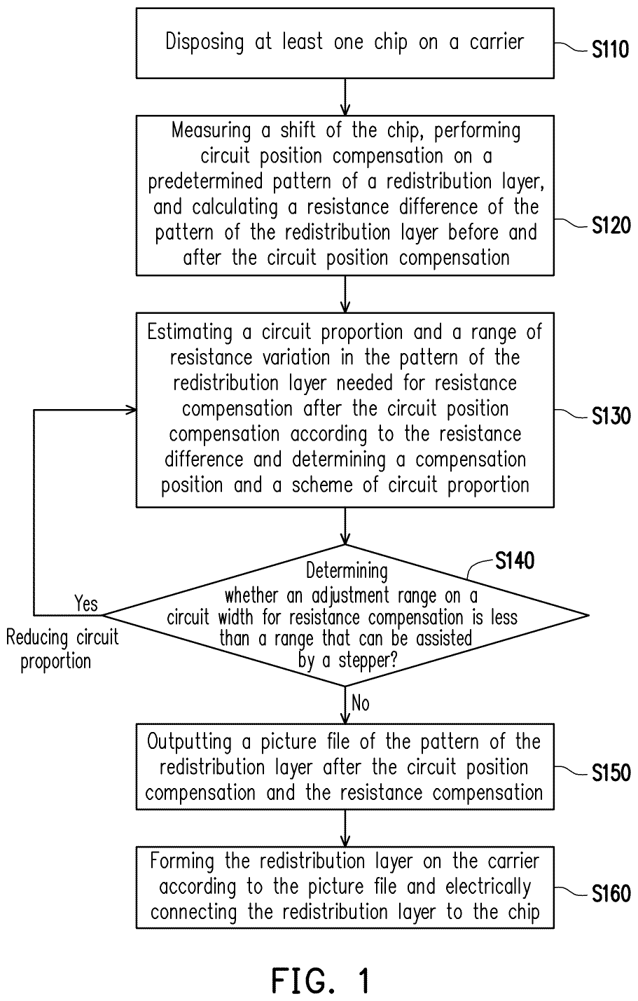

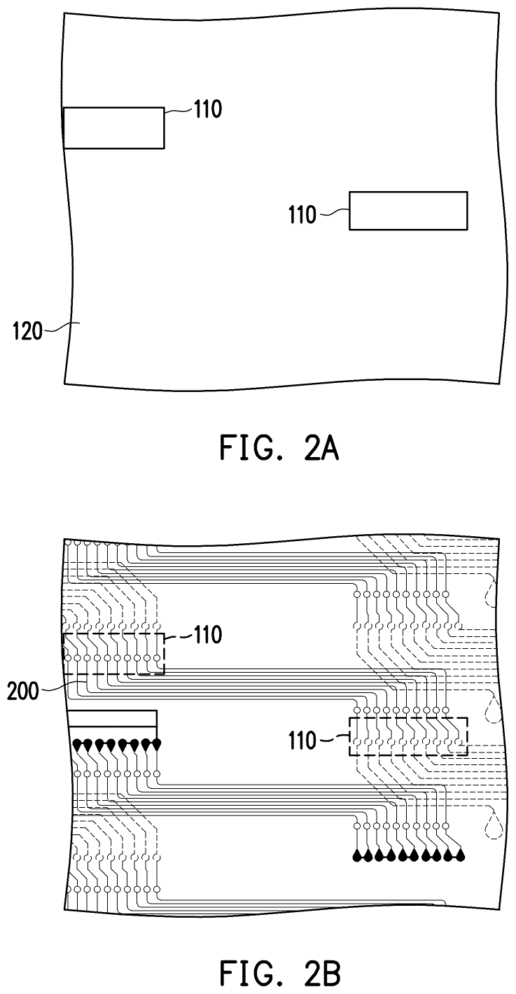

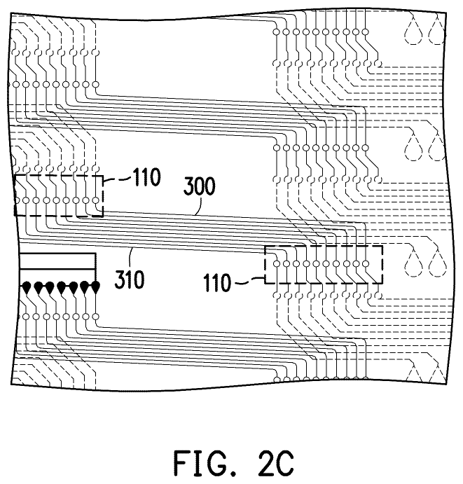

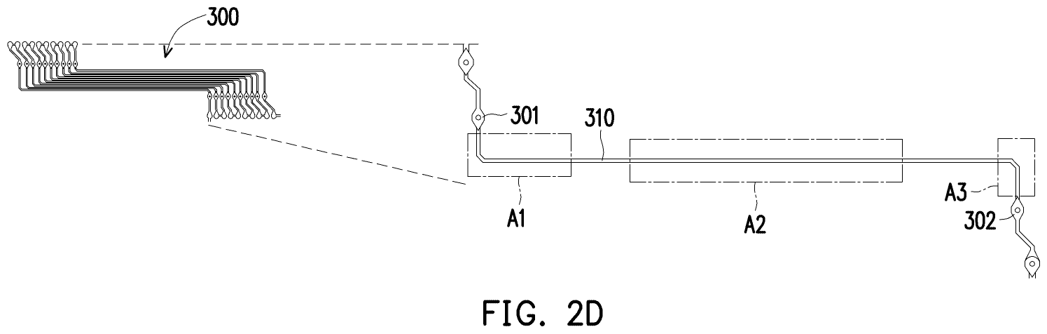

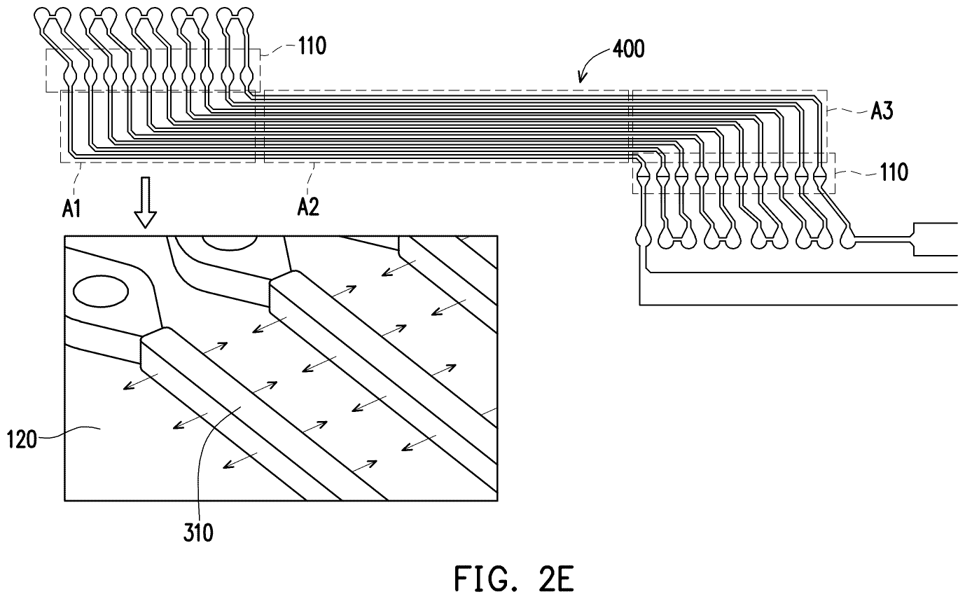

FIG. 1 is a flow chart of a circuit compensation method applied to pattern displacement according to an embodiment of the disclosure, and FIG. 2A to FIG. 2E are schematic top views illustrating the process flow of the circuit compensation method applied to pattern displacement of FIG. 1. With reference to FIG. 1 and FIG. 2A to FIG. 2E, the circuit compensation method applied to pattern displacement provided by this embodiment includes the following steps. First, as shown in FIG. 2A, step S110 is performed. At least one chip 110 is disposed on a carrier 120, for example, the chip 110 is bonded to the carrier 120. During the bonding process, the chip may be shifted relative to a predetermined position due to alignment errors or other factors. Next, as shown in FIG. 2B and FIG. 2C, step S120 is performed. The shift of the chip 110 is measured, circuit position compensation is performed on a predetermined pattern 200 (as shown in FIG. 2B) of a redistribution layer, so as to form a pattern 300 (as shown in FIG. 2C) of the redistribution layer after circuit position compensation, and resistance difference of the pattern of the redistribution layer before and after the circuit position compensation is calculated (i.e., the resistance difference between the pattern 200 of the redistribution layer and the pattern 300 of the redistribution layer). After that, as shown in FIG. 2D, step S130 is performed. A circuit proportion and a range of resistance variation in the pattern 300 of the redistribution layer needed for resistance compensation after the circuit position compensation is estimated according to the resistance difference. In this embodiment, a circuit proportion in region A1 is, for example, 20%, a circuit proportion in region A2 is, for example, 50%, and a circuit proportion in region A3 is, for example, 10%. The circuit proportion herein refers to the ratio of an area of a circuit 310 in the region (e.g., region A1, region A2, or region A3) where the resistance compensation is intended to be performed to an area of the entire circuit 310 from a contact 301 to a contact 302. Next, a compensation position and a scheme of circuit proportion is determined (i.e., determining which region of the circuit 310 is used for resistance compensation and its circuit proportion), and a circuit width, an area, a length, a pattern, or a combination thereof of the circuit 310 within the circuit proportion is adjusted according to the resistance difference. In this embodiment, for example, adjustment on the circuit width of the circuit 310 is treated as an example.

In this embodiment, step S140 may be performed next to determine whether an adjustment range on the circuit width for resistance compensation is less than a range that can be assisted by a stepper. If no, proceed to execute the following step S150, and if yes, re-select the scheme of circuit proportion, for example, by reducing the circuit proportion (i.e., selecting a smaller circuit proportion). To be specific, when fabricating circuits using a photolithography process, the stepper has a detection limit. Circuit width variations that are excessively small are undetectable and unachievable for the stepper. In this case, the circuit proportion may be reduced to increase the degree of circuit width adjustment corresponding to the resistance difference, so that a range that can be detected and assisted by the stepper is achieved.

Next, step S150 is performed, and a picture file of the pattern of the redistribution layer after the circuit position compensation and the resistance compensation is outputted. Subsequently, as shown in FIG. 2E, step S160 is performed, a redistribution layer 400 is formed on the carrier 120 according to the picture file, and the redistribution layer 400 is electrically connected to the chip 110. As shown in the enlarged view of FIG. 2E, it can be seen that the circuit width of the circuit 310 in the redistribution layer 400 is widened.

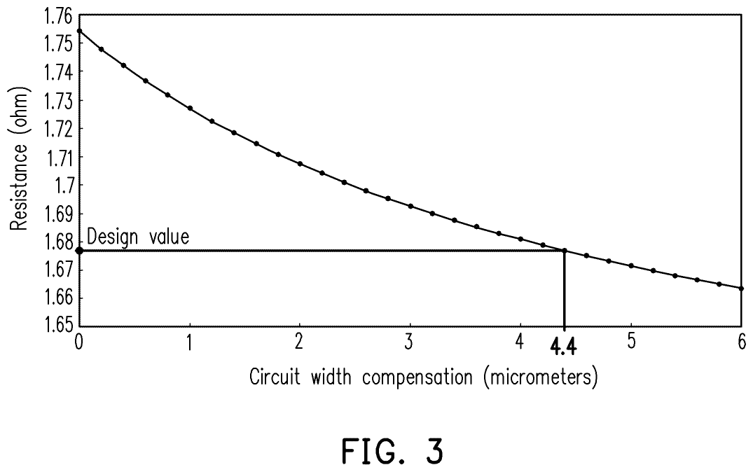

FIG. 3 is a curve graph of variation of circuit resistance with circuit width compensation. With reference to FIG. 2C, FIG. 2D, and FIG. 3, a resistance value of the circuit 310 in the pattern 300 of the redistribution layer after circuit position compensation but before resistance compensation (e.g., circuit width compensation) falls approximately between 1.75 and 1.76, which is a considerable difference from a design value that falls between 1.67 and 1.68. From the variation curve in FIG. 3, it can be seen that when the circuit width of the circuit 310 is compensated by 4.4 micrometers, the resistance of the circuit 310 may be restored to the design value. A detection range of the stepper for circuit width compensation may be, for example, 2 to 5 micrometers, and 4.4 micrometers falls within this range. Therefore, the circuit width compensation of 4.4 micrometers is within the range that can be assisted by the stepper.

The following Table 1 lists several examples of the aforementioned scheme of circuit proportion (i.e., the compensation scheme in Table 1):

TABLE 1

| Compensation | Circuit | \|Resistance | 10% < \|Resistance | 20% < \|Resistance |
|---|---|---|---|---|
| Scheme | Proportion | Difference\| ≤ 10% | Difference\| ≤ 20% | Difference\| ≤ 30% |
| A | 10% | 0 < circuit width | 100% < circuit width | 200% < circuit width |
| | | compensation | compensation | compensation |
| | | (increase or | (increase or | (increase or |
| | | decrease) ≤ 100% | decrease) ≤ 200% | decrease) ≤ 300% |
| B | 20% | 0 < circuit width | 50% < circuit width | 100% < circuit width |
| | | compensation | compensation | compensation |
| | | (increase or | (increase or | (increase or |
| | | decrease) ≤ 50% | decrease) ≤ 100% | decrease) ≤ 150% |
| C | 50% | 0 < circuit width | 20% < circuit width | 40% < circuit width |
| | | compensation | compensation | compensation |
| | | (increase or | (increase or | (increase or |
| | | decrease) ≤ 20% | decrease) ≤ 40% | decrease) ≤ 60% |
| D | 80% | 0 < circuit width | 12.5% < circuit width | 25% < circuit width |
| | | compensation | compensation | compensation |
| | | (increase or | (increase or | (increase or |
| | | decrease) ≤ 12.5% | decrease) ≤ 25% | decrease) ≤ 37.5% |
| E | 100% | 0 < circuit width | 10% < circuit width | 20% < circuit width |
| | | compensation | compensation | compensation |
| | | (increase or | (increase or | (increase or |
| | | decrease) ≤ 10% | decrease) ≤ 20% | decrease) ≤ 30% |

For instance, in compensation scheme A, in response to a circuit proportion of 10% and an absolute value of resistance difference less than or equal to 10%, the proportion (i.e., circuit width compensation in Table 1) of the circuit width or area of the circuit 310 may be adjusted to be greater than 0% and less than or equal to 100%, where the circuit width compensation may be an increase or decrease in circuit width. Similarly, in response to a circuit proportion of 10% and an absolute value of resistance difference greater than 10% and less than or equal to 20%, the proportion (i.e., circuit width compensation in Table 1) of the circuit width or area of the circuit 310 may be adjusted to be greater than 100% and less than or equal to 200%. The physical meanings of other scenarios in Table 1 can be inferred accordingly. For instance, in compensation scheme B, in response to a circuit proportion of 20% and an absolute value of resistance difference less than or equal to 10%, the proportion (i.e., circuit width compensation in Table 1) of the circuit width or area of may be adjusted to be greater than 0% and less than or equal to 50%. The physical meanings of other scenarios and other compensation schemes in Table 1 can be inferred similarly. In other embodiments, other compensation schemes may also involve simultaneously selecting two regions with different circuit proportions in the circuit 310 for resistance compensation (e.g., circuit width compensation), such as selecting two regions in the circuit 310 with circuit proportions of 10% and 20% respectively for resistance compensation (e.g., circuit width compensation). In other embodiments, it may also involve simultaneously selecting three or more regions with different circuit proportions in the circuit 310 for resistance compensation (e.g., circuit width compensation).

In this embodiment, a region (e.g., region A) with a larger circuit spacing in the pattern 300 of the redistribution layer after the circuit position compensation is used as a region for the resistance compensation. In this embodiment, the chip 110 may be a low-frequency signal chip. For instance, in an embodiment, the chip 110 may be a display panel driving chip with a frequency range of 1 Hz to 10 kHz. Alternatively, in another embodiment, the chip 110 may be a micro light-emitting diode chip.

In the circuit compensation method applied to pattern displacement provided by this embodiment, due to the formation of the redistribution layer 400 by means of the circuit position compensation and the resistance compensation, a circuit structure with good electrical quality may be formed. Further, the circuit compensation method applied to pattern displacement provided by this embodiment is suitable for a chip first process.

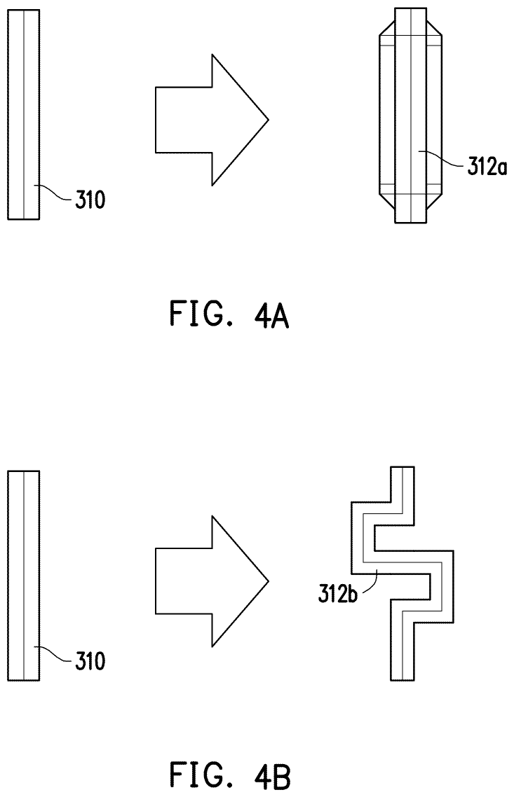

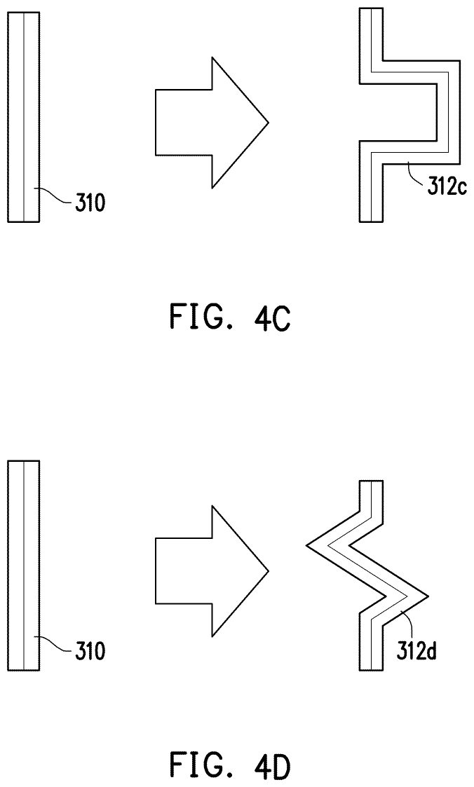

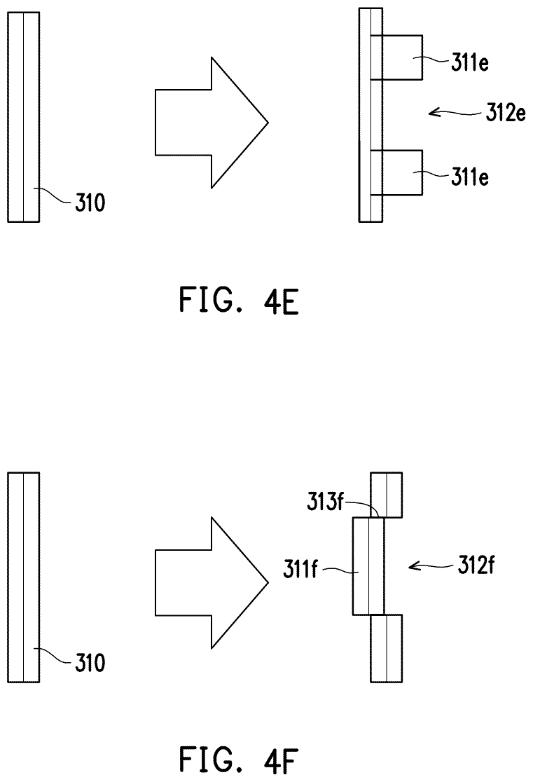

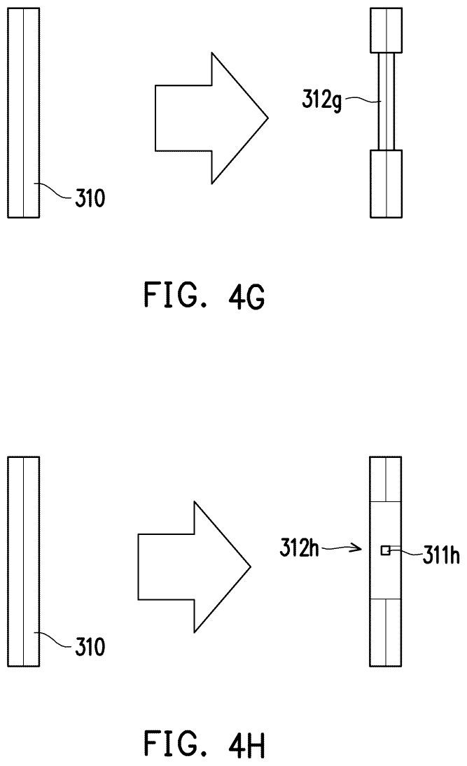

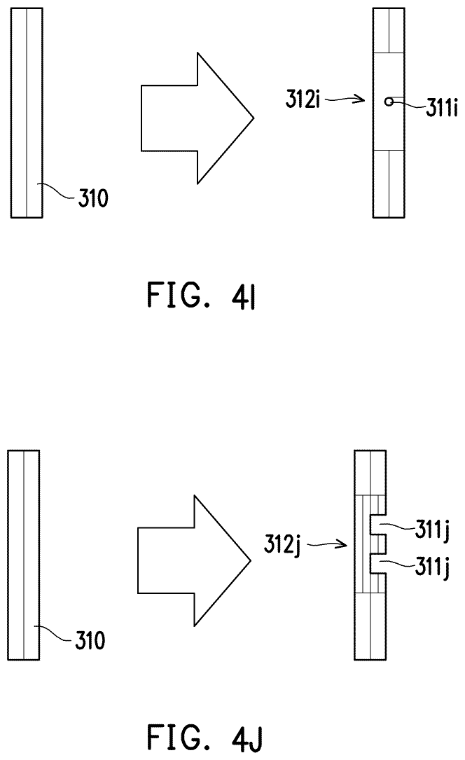

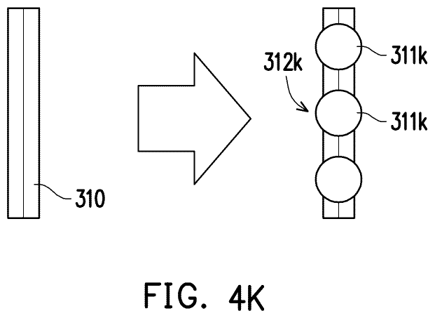

FIG. 4A to FIG. 4K are schematic top views illustrating a circuit before and after resistance compensation in the various embodiments of resistance compensation of FIG. 1. With reference to FIG. 4A, when the resistance of the circuit 310 after circuit position compensation increases, the circuit width of the circuit 310 may be increased to reduce the resistance, and a resistance compensation structure 312a is thereby formed. With reference to FIG. 4B, when the resistance of the circuit 310 after circuit position compensation decreases, 90-degree bends may be applied to both sides of the circuit to increase the resistance by increasing a circuit length, and a resistance compensation structure 312b is thereby formed. With reference to FIG. 4C, when the resistance of the circuit 310 after circuit position compensation decreases, a 90-degree bend may be applied to one side of the circuit to increase the resistance by increasing the circuit length, and a resistance compensation structure 312c is thereby formed. With reference to FIG. 4D, when the resistance of the circuit 310 after circuit position compensation decreases, a 45-degree bend may be applied to the circuit to increase the resistance by increasing the circuit length, and a resistance compensation structure 312d is thereby formed. With reference to FIG. 4E, when the resistance of the circuit 310 after circuit position compensation increases, at least one block 311e with a larger width may be added to the circuit to reduce the resistance, and a resistance compensation structure 312e is thereby formed. With reference to FIG. 4F, when the resistance of the circuit 310 after circuit position compensation decreases, connection between a partial region 311f of the circuit and other regions may be reduced, for example, by reducing a connection region 313f, to increase the resistance, and a resistance compensation structure 312f is thereby formed.

With reference to FIG. 4G, when the resistance of the circuit 310 after circuit position compensation decreases, the circuit width may be reduced to increase the resistance, and a resistance compensation structure 312g is thereby formed. With reference to FIG. 4H, when the resistance of the circuit 310 after circuit position compensation decreases, a partial region 311h of the circuit may be removed to increase the resistance, and a resistance compensation structure 312h is thereby formed, where the partial region 311h is, for example, a square region. With reference to FIG. 4I, when the resistance of the circuit 310 after circuit position compensation decreases, a partial region 311i of the circuit may be removed to increase the resistance, and a resistance compensation structure 312i is thereby formed, where the partial region 311i is, for example, a circular region. In other embodiments, the partial region 311i may also be a region of other shapes. With reference to FIG. 4J, when the resistance of the circuit 310 after circuit position compensation decreases, a partial region 311j of the circuit may be removed to increase the resistance, and a resistance compensation structure 312j is thereby formed, where the partial region 311j is, for example, located at an edge of the circuit and is, for example, a square region. However, in other embodiments, the partial region 311j may also be a region of other shapes. With reference to FIG. 4K, when the resistance of the circuit 310 after circuit position compensation increases, a part of the circuit may be enlarged to form an enlarged region 311k to reduce the resistance, and a resistance compensation structure 312k is thereby formed. In other embodiments, the enlarged region 311k may also be other regions that can increase the circuit width.

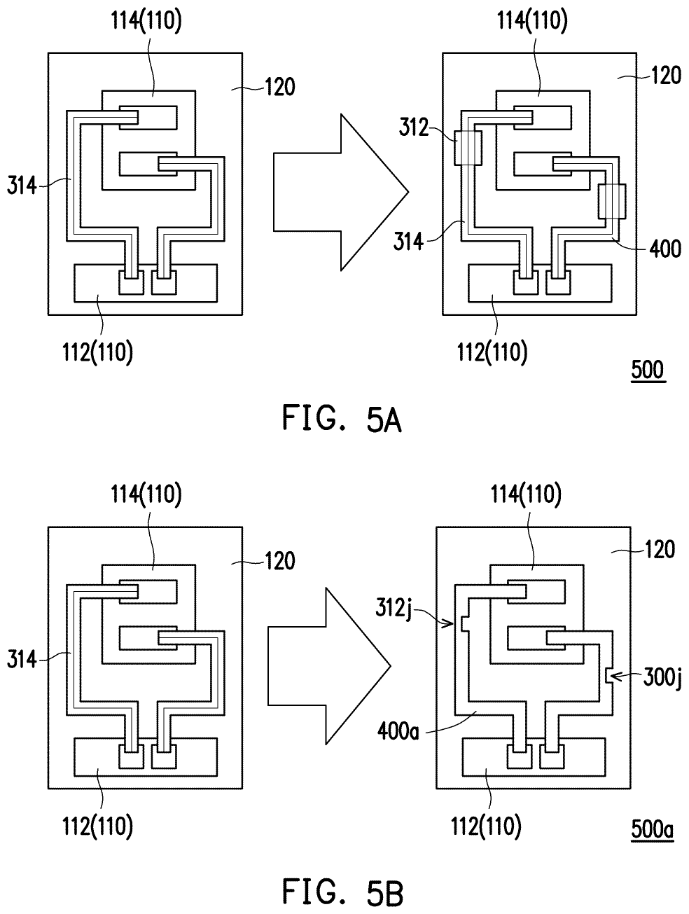

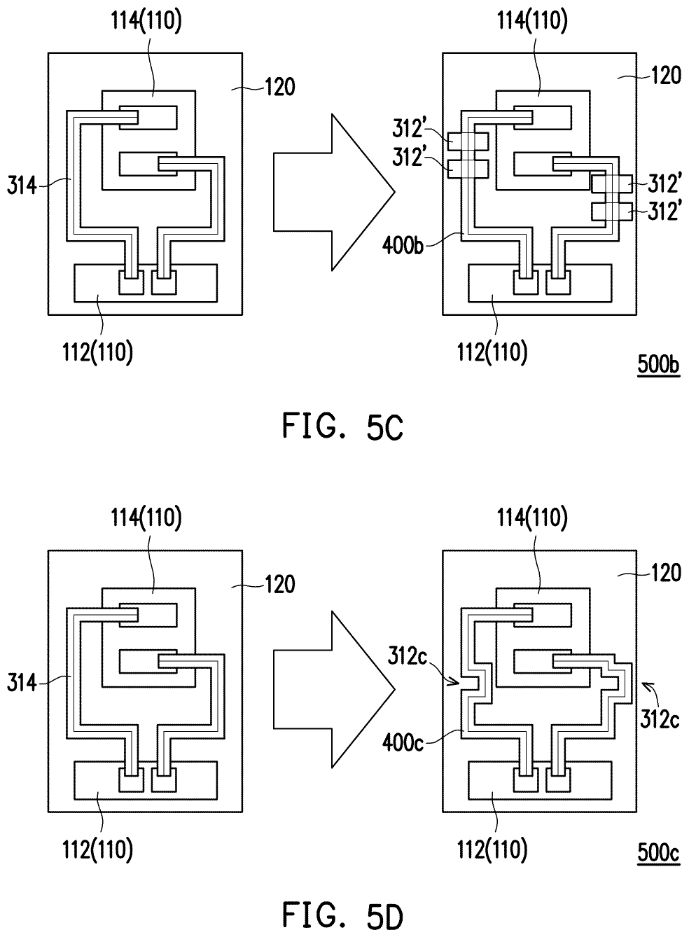

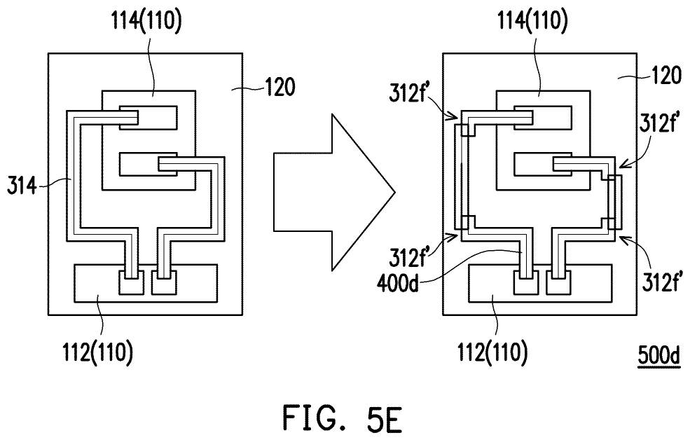

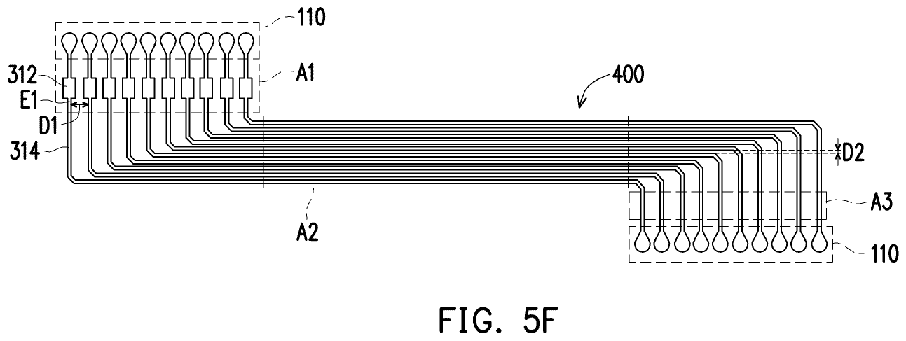

FIG. 5A to FIG. 5E are schematic top views illustrating a circuit structure before and after resistance compensation according to the embodiments of the disclosure. With reference to FIG. 5A first, a circuit structure 500 of this embodiment includes a carrier 120, a redistribution layer 400, and at least one chip 110. The redistribution layer 400 is disposed on the carrier 120 and has a normal circuit 314 and at least one resistance compensation structure 312 connected to each other. The resistance compensation structure 312 has a different circuit width, different area, different length, different pattern, or combinations thereof compared to the normal circuit 314. In FIG. 5A, different circuit widths or different areas are shown as examples. In this embodiment, the circuit width and area of the resistance compensation structure 312 are larger than those of the normal circuit 314, so that the resistance of the circuit may be effectively reduced. The at least one chip 110 is located on the carrier 120 and is electrically connected to the redistribution layer 400. In this embodiment, the at least one chip 110 includes a plurality of chips 110 and may be divided into driving chips 112 and micro light-emitting diode chips 114. The driving chips 112 are used to drive the micro light-emitting diode chips 114 to emit light through the redistribution layer 400.

In this embodiment, the circuit structure 500 may be fabricated through the circuit compensation method applied to pattern displacement as shown in FIG. 1. Due to the adoption of the resistance compensation structure 312, the circuit structure 500 may exhibit good electrical quality.

The circuit structure 500 may also be applied to the circuit structure as shown in FIG. 2E, where the resistance compensation structure 312 is located in a first region (e.g., region A1, region A2, or region A3 in FIG. 2E), and the normal circuit 314 is located in a second region (e.g., the remaining region outside the first region). The circuit proportion of the resistance compensation structure 312 may be as described in the embodiments mentioned in Table 1 in the foregoing paragraphs. For instance, in the circuit structure generated in compensation scheme A, the circuit proportion is 10%, the absolute value of the resistance difference caused by chip displacement in the normal circuit 314 of the redistribution layer 400 is less than or equal to 10%, and the ratio of circuit width variation or area variation of the resistance compensation structure 312 relative to the normal circuit 314 is greater than 0% and less than or equal to 100%. In the circuit structure generated in compensation scheme B, the circuit proportion is 20%, the absolute value of the resistance difference caused by chip displacement in the normal circuit 314 of the redistribution layer 400 is less than or equal to 10%, and the ratio of circuit width variation or area variation of the resistance compensation structure 312 relative to the normal circuit 314 is greater than 0% and less than or equal to 50%. The details of other compensation schemes mentioned in Table 1 of the foregoing embodiments may be inferred by analogy and are not repeated here.

In addition, in an embodiment, as shown in FIG. 5F, a circuit spacing D1 at an end E1 where the normal circuit 314 is connected to the resistance compensation structure 312 is greater than an average circuit spacing of the normal circuit 314. For instance, the end E1 where the normal circuit 314 is connected to the resistance compensation structure 312 is located in a region with a larger circuit spacing (for example, the circuit spacing D1 in the region A1 of FIG. 5F is greater than a circuit spacing D2 between the normal circuits 314 in the region A2, and the resistance compensation structure 312 is located in the region A1). Herein, the average circuit spacing of the normal circuit 314 may be defined as an area of an interval region between two adjacent normal circuits 314 divided by a total length of one of these two adjacent normal circuits 314.

Circuit structures 500a to 500d in FIG. 5B to FIG. 5E are similar to the circuit structure 500 in FIG. 5A, with the main difference being the different resistance compensation structures adopted in the redistribution layer. The main difference is described in detail in the following paragraphs.

With reference to FIG. 5B, a redistribution layer 400a of the circuit structure 500a in this embodiment adopts the resistance compensation structure 312j as shown in FIG. 4J to increase the resistance of the circuit. With reference to FIG. 5C, a redistribution layer 400b of the circuit structure 500b in this embodiment adopts resistance compensation structures 312′ to reduce the resistance of the circuit. The resistance compensation structures 312′ are similar to the resistance compensation structure 312 in FIG. 5A, except that the resistance compensation structures 312′ have a smaller area and a larger quantity in comparison.

With reference to FIG. 5D, a redistribution layer 400c of the circuit structure 500c in this embodiment adopts the resistance compensation structures 312c as shown in FIG. 4C to increase the resistance of the circuit. With reference to FIG. 5E, a redistribution layer 400d of the circuit structure 500d in this embodiment adopts a structure similar to FIG. 4F, where the connection between the partial region 311f of the circuit and other regions is reduced to increase resistance, so a resistance compensation structure 312f is thereby formed. In other embodiments, the redistribution layer of the circuit structure may also adopt the resistance compensation structures 312a to 312k shown in FIG. 4A to FIG. 4K to increase or decrease the resistance.

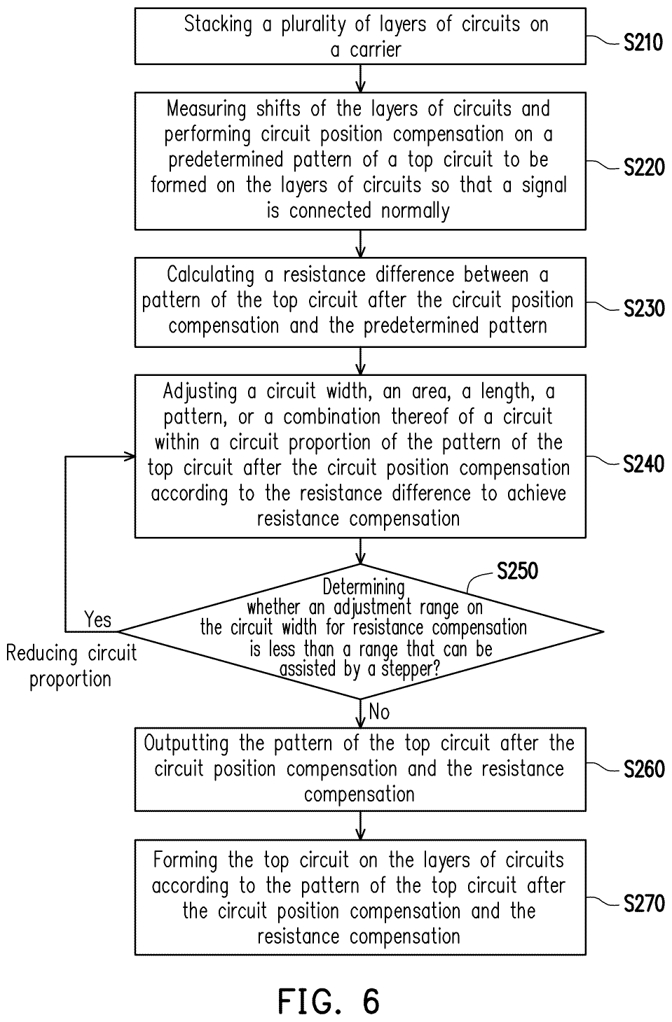

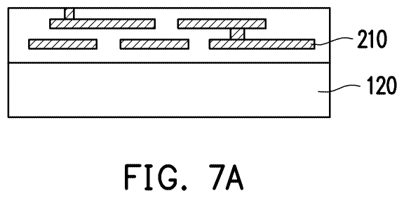

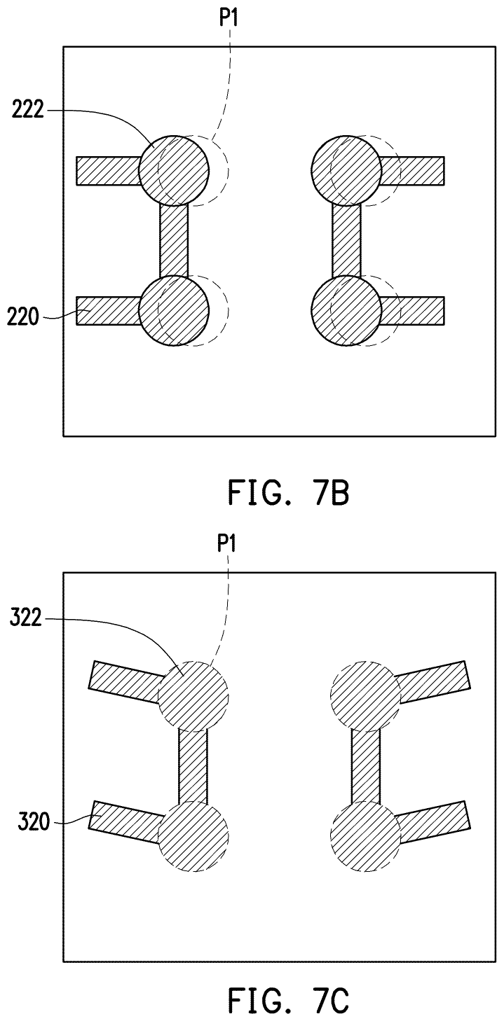

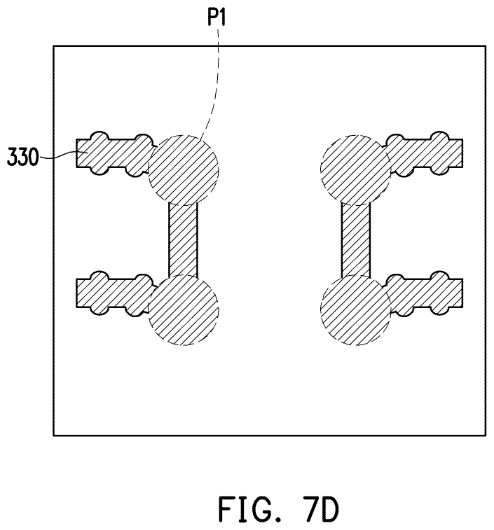

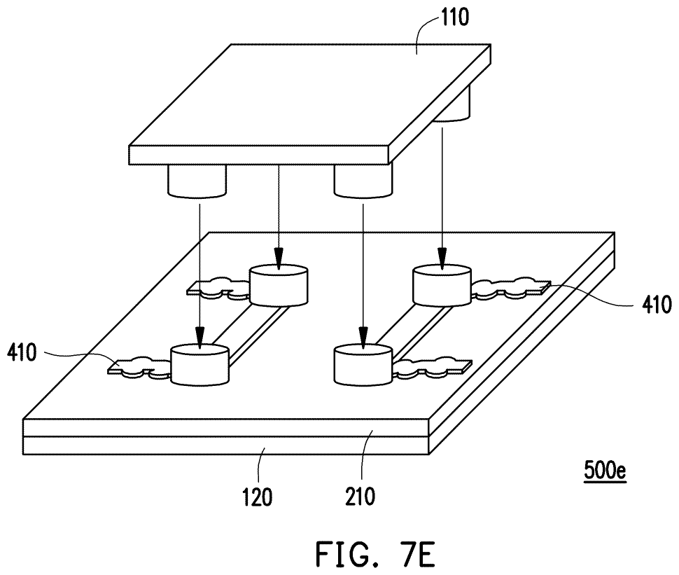

FIG. 6 is a flow chart of a circuit compensation method applied to pattern displacement according to another embodiment of the disclosure, and FIG. 7A to FIG. 7E are schematic top views illustrating the process flow of the circuit compensation method applied to pattern displacement of FIG. 6. With reference to FIG. 6 and FIG. 7A to FIG. 7E, the circuit compensation method applied to pattern displacement provided by this embodiment includes the following steps. First, as shown in FIG. 7A, step S210 is performed to stack a plurality of layers of circuits 210 on a carrier 120, where these layers of circuits 210 are, for example, a redistribution layer. In this embodiment, the carrier 120 is, for example, larger than the size of a G2.5 generation display panel, for example, larger than a size with a length and width of 370 millimeters and 470 millimeters respectively, that is, the carrier 120 is, for example, a large-size carrier. During the manufacturing process of the redistribution layer, due to the difference in thermal expansion coefficients between dielectric materials and metal materials, circuits on large-size carriers are prone to shift, resulting in each layer of the layers of circuits 210 being shifted. Herein, step S220 may be performed next to measure shifts of the layers of circuits 210, and circuit position compensation is performed on the a predetermined pattern 220 (as shown in FIG. 7B) of a top circuit to be formed on the layers of circuits 210, for example, compensating the predetermined pattern into a pattern 320 of the top circuit as shown in FIG. 7C, so as to ensure normal signal connection. To be specific, the circuit compensation method applied to pattern displacement in this embodiment may be applied in the redistribution layer first process. Since the layers of circuits 210 are shifted, when the predetermined pattern 220 of the top circuit is formed thereon, a pad position 222 of the predetermined pattern 220 of the top circuit may be shifted relative to a predetermined pad position P1 where the chip 110 is intended to be bonded. A pad position 322 of the pattern 320 of the top circuit after circuit position compensation is adjusted to match the predetermined pad position P1.

Next, step S230 is performed, and a resistance difference between the pattern 320 (as shown in FIG. 7C) of the top circuit after the circuit position compensation and the predetermined pattern 220 (as shown in FIG. 7B) is calculated. Next, step S240 is performed, and a circuit width, an area, a length, a pattern, or a combination thereof of a circuit within a circuit proportion of the pattern 320 of the top circuit after the circuit position compensation are adjusted according to the resistance difference to achieve resistance compensation, that is, to compensate the pattern into the pattern 330 of the top circuit as shown in FIG. 7C. The circuit proportion and the method of adjusting the circuit width, area, length, pattern, or combination thereof may be the same as in the foregoing embodiments, and description thereof is not repeated herein. That is, the circuit proportion and a range of resistance variation in the pattern 320 of the top circuit needed for the resistance compensation after the circuit position compensation may be estimated according to the resistance difference before the resistance compensation. Next, a compensation position and a scheme of circuit proportion are determined to perform the resistance compensation. In an embodiment, the region with larger circuit spacing in the pattern 320 of the top circuit after circuit position compensation is used as the region for resistance compensation.

After that, step S250 is performed to determine whether an adjustment range on the circuit width for resistance compensation is less than a range that can be assisted by a stepper. If no, proceed to execute the following step S260, and if yes, re-select the scheme of circuit proportion, for example, by reducing the circuit proportion (i.e., selecting a smaller circuit proportion). The method of re-selecting the scheme of circuit proportion is as described in the foregoing embodiments, so description thereof is not be repeated herein.

Next, step S260 is performed to output the pattern 330 of the top circuit after circuit position compensation and resistance compensation (as shown in FIG. 7D). After that, as shown in FIG. 7E, step S270 is performed, and a top circuit 410 is formed on the layers of circuits 210 according to the pattern 330 of the top circuit after the circuit position compensation and the resistance compensation.

In this embodiment, in the circuit compensation method applied to pattern displacement, at least one chip 110 is disposed on the top circuit 410, and the chip 110 is electrically connected to the top circuit 410. The chip 110 may be the chip 110 described in the foregoing embodiments, so description thereof is not repeated herein.

In the circuit compensation method applied to pattern displacement provided by this embodiment, due to the formation of the top circuit by means of the circuit position compensation and the resistance compensation, a circuit structure 500e with good electrical quality may be formed.

In view of the foregoing, in the circuit compensation method applied to pattern displacement provided by the embodiments of the disclosure, due to the formation of the redistribution layer or the top circuit by means of the circuit position compensation and the resistance compensation, a circuit structure with good electrical quality may be formed. In the circuit structure provided by the embodiments of the disclosure, due to the adoption of the resistance compensation structure, the circuit structure may exhibit good electrical quality.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A circuit compensation method applied to pattern displacement, comprising:
disposing at least one chip on a carrier;
measuring a shift of the at least one chip, performing circuit position compensation on a predetermined pattern of a redistribution layer, and calculating a resistance difference of the pattern of the redistribution layer before and after the circuit position compensation;
estimating a circuit proportion and a range of resistance variation in the pattern of the redistribution layer needed for resistance compensation after the circuit position compensation according to the resistance difference;
determining a compensation position and a scheme of circuit proportion and adjusting a circuit width, an area, a length, a pattern, or a combination thereof of a circuit within the circuit proportion according to the resistance difference;
outputting a picture file of the pattern of the redistribution layer after the circuit position compensation and the resistance compensation; and
forming the redistribution layer on the carrier according to the picture file and electrically connecting the redistribution layer to the at least one chip.

2. The circuit compensation method applied to pattern displacement according to claim 1, wherein in response to the circuit proportion being 10% and an absolute value of the resistance difference being less than or equal to 10%, a proportion of the circuit width or the area is adjusted to be greater than 0% and less than or equal to 100%.

3. The circuit compensation method applied to pattern displacement according to claim 1, wherein in response to the circuit proportion being 20% and an absolute value of the resistance difference being less than or equal to 10%, a proportion of the circuit width or the area is adjusted to be greater than 0% and less than or equal to 50%.

4. The circuit compensation method applied to pattern displacement according to claim 1, wherein a region with a larger circuit spacing in the pattern of the redistribution layer after the circuit position compensation is used as a region for the resistance compensation.

5. The circuit compensation method applied to pattern displacement according to claim 1, wherein in response to an adjustment range of the circuit width of the resistance compensation being smaller than a range assisted by a stepper, the scheme of circuit proportion is reselected.

6. A circuit compensation method applied to pattern displacement, comprising:
stacking a plurality of layers of circuits on a carrier;
measuring shifts of the layers of circuits and performing circuit position compensation on a predetermined pattern of a top circuit to be formed on the layers of circuits so that a signal is connected normally;
calculating a resistance difference between a pattern of the top circuit after the circuit position compensation and the predetermined pattern;
adjusting a circuit width, an area, a length, a pattern, or a combination thereof of a circuit within a circuit proportion of the pattern of the top circuit after the circuit position compensation according to the resistance difference to achieve resistance compensation;
outputting the pattern of the top circuit after the circuit position compensation and the resistance compensation; and
forming the top circuit on the layers of circuits according to the pattern of the top circuit after the circuit position compensation and the resistance compensation.

7. The circuit compensation method applied to pattern displacement according to claim 6, further comprising disposing at least one chip on the top circuit electrically connecting the at least one chip to the top circuit.

8. The circuit compensation method applied to pattern displacement according to claim 6, further comprising
estimating the circuit proportion and a range of resistance variation in the pattern of the top circuit needed for the resistance compensation after the circuit position compensation according to the resistance difference before the resistance compensation; and
determining a compensation position and a scheme of circuit proportion to perform the resistance compensation.

9. The circuit compensation method applied to pattern displacement according to claim 8, wherein in response to the circuit proportion being 10% and an absolute value of the resistance difference being less than or equal to 10%, a proportion of the circuit width or the area is adjusted to be greater than 0% and less than or equal to 100%.

10. The circuit compensation method applied to pattern displacement according to claim 8, wherein in response to the circuit proportion being 20% and an absolute value of the resistance difference being less than or equal to 10%, a proportion of the circuit width or the area is adjusted to be greater than 0% and less than or equal to 50%.

11. The circuit compensation method applied to pattern displacement according to claim 8, wherein in response to an adjustment range of the circuit width of the resistance compensation being smaller than a range assisted by a stepper, the scheme of circuit proportion is reselected.

12. The circuit compensation method applied to pattern displacement according to claim 6, wherein a region with a larger circuit spacing in the pattern of the top circuit after the circuit position compensation is used as a region for the resistance compensation.

13. A circuit structure, comprising:
a carrier;
a redistribution layer disposed on the carrier and having a normal circuit located in a second region and a resistance compensation structure located in a first region, wherein the resistance compensation structure has a circuit proportion and has a different circuit width, a different area, a different length, a different pattern, or a combination thereof compared to the normal circuit; and
at least one chip located on the carrier and electrically connected to the redistribution layer, wherein resistance of the circuit structure does not change due to chip displacement.

14. The circuit structure according to claim 13, wherein the at least one chip is a low-frequency signal chip or a display panel driver chip with a frequency ranging from 1 Hz to 10 kHz, or the at least one chip is a micro light-emitting diode chip.

15. The circuit structure according to claim 13, wherein the circuit proportion is 10%, an absolute value of the resistance difference of the normal circuit of the redistribution layer caused by the chip displacement is less than or equal to 10%, and a proportion of a circuit width variation or an area variation of the resistance compensation structure relative to the normal circuit is greater than 0% and less than or equal to 100%.

16. The circuit structure according to claim 13, wherein the circuit proportion is 20%, an absolute value of the resistance difference of the normal circuit of the redistribution layer caused by the chip displacement is less than or equal to 10%, and a proportion of a circuit width variation or an area variation of the resistance compensation structure relative to the normal circuit is greater than 0% and less than or equal to 50%.

17. The circuit structure according to claim 13, wherein a circuit spacing of one end of the normal circuit connected to the resistance compensation structure is greater than an average circuit spacing of the normal circuit.
